(19) United States
(12) Patent Application Publication
(10) Pub. No.: US 2021/0207263 A1
(43) Pub. Date: Jul. 8, 2021

(54) PROCEDURE FOR COATING COMPONENT SURFACES UNDER VACUUM AND THE VACUUM COATING SYSTEM USED FOR THIS PURPOSE

(71) Applicant: Hella GmbH & Co. KGaA, Lippstadt (DE)

(72) Inventors: Ralf Rochotzki, Lippstadt (DE); Frank Hartmann, Lippstadt (DE); Egbert Rath, Lippstadt (DE); Martin Eickenbusch, Lippetal (DE)

(21) Appl. No.: 16/071,312

(22) PCT Filed: Jan. 17, 2017
(86) PCT No.: PCT/EP2017/050872

§ 371 Date: Jul. 19, 2018

(30) Foreign Application Priority Data
Jan. 25, 2016 (DE) 10 2016 101 197.5

(51) Int. Cl. C23C 14/56; C23C 16/44; C23C 16/458; C23C 16/513; C23C 16/54

(52) U.S. Cl. CPC C23C 14/568; C23C 16/4412; C23C 16/54; C23C 16/513; C23C 16/4588

(57) ABSTRACT

A procedure for coating the surfaces of a component under vacuum using a vacuum coating system is disclosed. The procedure includes at least two of the following process steps: a) Plasma activation of the component surface to be coated in an evacuated plasma activation chamber and/or b) applying the coat in an evacuated coating chamber and/or c) plasma polymerization for creating a protective coating on the previously applied coating in an evacuated plasma polymerization chamber. The plasma activation chamber and/or the coating chamber and/or the plasma polymerization chamber are ventilated and opened between at least two of the aforementioned process steps, and the component is fed to the subsequent process step.

### CROSS REFERENCE

This application claims priority to PCT Application No. PCT/EP2017/050872, filed Jan. 17, 2017, which itself claims priority to German Patent Application 10 2016 101197.5, filed Jan. 25, 2016, the entirety of both of which are hereby incorporated by reference.

### FIELD OF THE INVENTION

This invention consists of a procedure for coating the surfaces of a component under vacuum using a vacuum coating system, whereby the procedure includes at least two of the following process steps: a) Plasma-activation of the component surface to be coated in an evacuated plasma activation chamber and/or b) applying the coat in an evacuated coating chamber and/or c) plasma polymerization to create a protective coating on the previously applied coating in an evacuated plasma polymerization chamber.

### BACKGROUND

Procedures for coating a component surface using a vacuum coating system are listed in order to metallize the surface of 3D components (among other reasons). For example, a metal coating is applied to headlamp reflectors or decorative components such as screens and the like. Optionally, upstream plasma activation can be used (depending on the material to be coated, such as aluminum or stainless steel), using a CVD procedure in a first chamber, which is evacuated in order to perform the procedure. This is followed by the coating process itself, which is a necessary process step regardless of the material to be coated. This may entail vapor deposition or sputtering the metallic reflective coating, particularly using the PVD procedure under vacuum. Then, plasma polymerization can create a protective coating under vacuum which, in turn, is based on the CVD procedure. Once again, the necessity of the process step for plasma polymerization is dependent on the material to be coated.

Nowadays, conventional vacuum coating system designs consist either of a single, appropriately large process chamber in which the various process steps are carried out consecutively, or several process chambers are provided in which the process steps are mostly carried out in parallel and the treated parts are transported from chamber to chamber. In both cases, process control is carried out without interrupting the vacuum. If several process chambers are used, then the air lock system must be provided between the individual chambers in order to maintain the vacuum in the chamber in question to the greatest extent possible. “Under a vacuum” refers to a pressure below the atmospheric pressure that is sufficient to carry out the corresponding process step. Consequently, evacuation describes every degree of pressure below the pressure present outside the process chamber.

For example, DE 103 52 144 B4 shows a multi-chamber principle of a vacuum coating system, whereby complex air lock systems are provided between the individual chambers. In addition, air locks between the individual chamber capacities are included in DE 198 08 163 C1.

Additional coating systems with a multi-chamber principle are included in DE 196 24 609 B4 and U.S. Pat. No. 6,554,980 B1.

Maintaining a vacuum for all the consecutive process steps means that, in multi-chamber systems, components must be transported from process chamber to process chamber under vacuum. This issue can be solved using technically complex designs such as corresponding vacuum feedthroughs for mechanical component movements. However, this solution is cost-intensive and associated with high maintenance costs.

For the solutions with just one process chamber in which processes are carried out consecutively, limits are set on the miniaturization, particularly due to the various procedural requirements. This is because not every process requires the same space and, in particular, cannot be operated using the same equipment (e.g. electrodes). This means that modern production concepts for individual part coating after the flow production, the so-called one-piece flow, are not sufficiently supported. The sequential processing of various technological steps in a chamber can also mutually influence and contaminate processes, which can cause the process result to worsen substantially.

For multi-chamber systems and parallel performance of various technological process steps, especially for automated vacuum coating systems with extremely short cycle times (ex. less than a minute), a high output can be reached, but the expense for systems engineering for the corresponding passage of the component from chamber to chamber is high.

DE 197 04 947 A1 shows an example of this. It includes a procedure and device for coat protection of reflective coats with several two-part process chambers. The internal parts of the process chambers are arranged in a rotary indexing table and are designed to hold the component. As a result, these internal process chamber parts can be overlapped with the consecutive stations to ensure that the components to be coated can be moved from station to station. The vacuum is maintained when switching stations. An internal wall cylinder is set up on the rotary indexing table, and this cylinder contains the internal parts of the process chambers. The internal wall cylinder is connected with the rotary indexing table in a rotatable position and operates in a volume chamber wall designed as a circular cylinder in which the external process chamber parts are set up by station. So, for example, every 90° around the rotary indexing axis, the internal parts are overlapped with the external parts of the process chambers whereby, for example, three process stations are provided and a removal option can be provided at a station. The synchronized switchover of the internal and external chamber parts with one another while maintaining the vacuum in the chamber parts requires substantial systems engineering costs, as substantial sealing issues in particular have to be overcome to maintain the vacuum when switching the internal and external chamber parts.

### SUMMARY OF THE INVENTION

The purpose of the invention is the embodiment of a procedure for coating surfaces of a component under vacuum and preparing the vacuum coating system to be used, whereby the plant engineering costs shall be minimized to the greatest extent possible and whereby parallel performance of individual process steps for several components shall be possible. In particular, the procedure shall be improved further based on a multi-chamber principle of the vacuum coating system.

This purpose is fulfilled starting with a procedure for coating the surfaces of a component in accordance with the umbrella term of claim 1 and starting with a vacuum coating system in accordance with the umbrella term of claim 6 with the respective distinguishing features. Advantageous embodiments of the invention are specified in the dependent claims.

The inventive procedure ensures that the plasma activation chamber and/or coating chamber and/or plasma polymerization chamber are ventilated and opened between at least two of the aforementioned process steps, and the component is fed to the subsequent process step. If a reduced system output is accepted, some individual process steps can be omitted for special handling processes.

The invention is based on the idea of avoiding using complex air lock technology between the process chambers by ventilating and opening the respective process chamber after each performed process step. Preferably, ventilation and opening are performed simultaneously to ensure that at least two or three components are being machined at a given time in the vacuum coating system. A first component is activated in the plasma activation chamber using plasma. A second component is coated in the coating chamber and a third component is subjected to plasma polymerization in the plasma polymerization chamber to create a corresponding protective coating. Here, only two of the three chambers can be utilized to use and design the system, whereby the coating chamber is a chamber that is required for all process types.

The special advantage of the inventive procedure is the high output, because all three chambers are closed, evacuated, ventilated and closed again simultaneously, ensuring that each of the components can be forwarded to a chamber. Ventilation and opening of the respective chamber after individual process steps eliminates the need to design air lock systems between the chambers. However, because the individual chambers can be evacuated simultaneously, the evacuation that is continuously required does not cause any time-related disadvantages. After plasma activation, the plasma activation chamber shall be ventilated and opened and the component can be transferred from the plasma activation chamber to the coating chamber and/or the coating chamber is ventilated and opened and the component is transferred from the coating chamber to the plasma activation chamber after applying the coat.

Another advantage of the procedure is achieved by coating several components in a cycle sequence in the vacuum coating system, whereby evacuation, ventilation and opening of the plasma activation chamber, coating chamber and plasma activation chamber are carried out simultaneously. If the components are delivered to the vacuum coating system, they are first inserted into the plasma activation chamber, while the preceding component is already being transferred to the coating chamber and the component that precedes this component is being transferred to the plasma polymerization chamber. This cycle sequence is continued component-by-component to ensure that the cycle frequency is targeted toward the cycle sequence for transferring the respective components. Dimensioning of the individual tools for carrying out the process steps. This means that the plasma activation tools, coat application tools and plasma polymerization tools are dimensioned to one another and operated using process parameters, meaning that, for the most part, they require the same process time.

An additional advantage is achieved if the vacuum is generated in the plasma activation chamber, in the coating chamber and in the plasma polymerization chamber using a shared vacuum pump. The vacuum pump can be designed as a correspondingly large backing vacuum pumping station and installed near the chamber to create pipes between the pumping station and chambers that are as short as possible. All three chambers are connected with the vacuum pump via a corresponding pipe system.

In addition to evacuation using the backing vacuum pumping station, it can be ensured that an auxiliary vacuum pump is available for even more powerful evacuation of the coating chamber. This pump is activated for further evacuation of the coating chamber, particularly through opening a valve, after joint evacuation of the chambers by the backing vacuum pump. Coating requires a vacuum that has an even lower atmospheric pressure than the vacuum in the chamber for plasma activation and in the chamber for plasma polymerization. A corresponding slide valve or suitable valve of another design is provided between the pipe system of the backing vacuum pump and coating chamber to ensure that the auxiliary vacuum pump still has a fluid connection with the coating chamber.

Another advantage is that the process steps for inserting the components, evacuation, the respective process flow, ventilation and opening the three chambers are carried out simultaneously, which is what was in mind when the vacuum coating system was designed. For example, an opening and closing mechanism is provided, which initiates movement of at least some parts of all three chambers simultaneously and physically connects them.

Furthermore, the invention is targeted toward a vacuum coating system for coating surfaces of a component under vacuum that features the following: plasma activation chamber for plasma activation of the component surface to be coated; a coating chamber for applying the coat and a plasma polymerization chamber for creating a protective coating on the previously applied coating using plasma polymerization. Here, the plasma activation chamber, coating chamber and/or plasma polymerization chamber each have a first chamber part in which tools for plasma activation, coating application and/or plasma polymerization are designed, and each has a second chamber that is designed to hold the component. In accordance with the inventive object, the second chamber parts are arranged such that they can move against the first chamber parts and can be ventilated, switched in cycles, closed again and evacuated between at least two process steps when the components are switched.

The inventive design of the vacuum coating system is further improved by ensuring that only one vacuum pump is set up, particularly a vacuum pumping system that can be used to generate the vacuum simultaneously in the plasma activation chamber, coating chamber and/or plasma polymerization chamber using a shared vacuum pump. The vacuum pump can be used as a backing vacuum pump and/or fine vacuum pump and an auxiliary vacuum pump can be provided that further evacuates the coating chamber. In particular, the vacuum pumps can be designed in an assembly as a vacuum pumping station.

The vacuum pump is connected with the first chamber parts that can be arranged in stationary positions in the vacuum coating system. The second chamber parts are arranged in a movable position in the vacuum coating system and designed such that they are compatible with each of the first chamber parts. This ensures that the second chamber parts can be moved from chamber to chamber with the held components, namely from a first chamber part to the next first chamber part, and each can form a seal on the first chamber parts. It is not until this point that the vital advantage is achieved that the vacuum coating system can be designed with a rotary indexing table, and the second chamber parts are held on the rotary indexing table. Using the rotary indexing table, the second chamber parts are moved against the first chamber parts.

Unlike the process sequence for plasma activation, coat application and plasma polymerization, plasma polymerization can be carried out in place of plasma activation in the plasma activation chamber. From a technological perspective, these are very similar processes. Furthermore, there can be special processes that omit 1 or 2 of the 3 process steps.

### BRIEF DESCRIPTION OF THE DRAWINGS

Reference is now made more particularly to the drawings, which illustrate the best presently known mode of carrying out the invention and wherein similar reference characters indicate the same parts throughout the views.

FIG. 1A—FIG. 1E are respective views of the plasma activation chamber, coating chamber and plasma polymerization chamber, whereby a component is moved through the chambers.

FIG. 2 is a perspective schematic view of a vacuum coating system with the features of this invention.

### DETAILED DESCRIPTION OF THE DRAWINGS

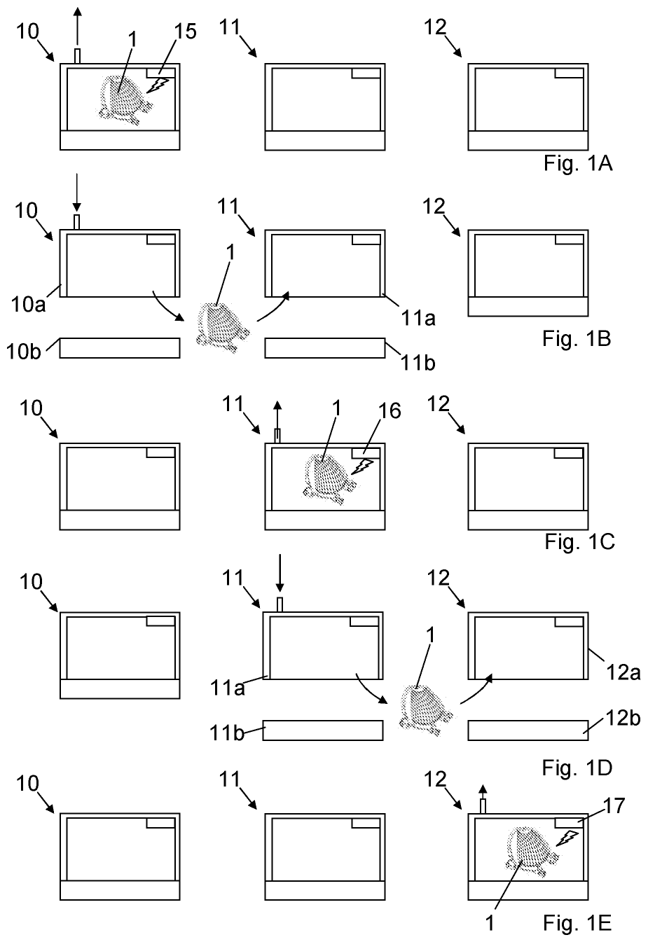

FIG. 1A shows the plasma activation chamber (10), coating chamber (11) and plasma polymerization chamber (12), which means that there are three chambers in the displayed embodiment, whereby the component (1) is held in the plasma activation chamber (10). In the plasma activation chamber (10), there is a tool (15) for plasma activation that can be used for plasma activation of the component surface to be coated (1).

FIG. 1B shows the plasma activation chamber (10), coating chamber (11) and plasma polymerization chamber (12), whereby the plasma activation chamber (10) and the coating chamber (11) are each opened. The opening is created between the first chamber part (10a) and second chamber part (10b) of the plasma activation chamber (10) and the first chamber part 11a and the second chamber part (11b) of the coating chamber (11). When opening, the component (1) under atmosphere can be transferred from the plasma activation chamber (10) to the coating chamber (11).

FIG. 1C shows the plasma activation chamber (10), coating chamber (11) and plasma polymerization chamber (12), all of which are in a closed state, and the coating chamber (11) has a tool (16) for applying the coat to the component (1) and this tool (16) is activated.

FIG. 1D shows the plasma activation chamber (10), coating chamber (11) and plasma polymerization chamber (12), whereby the coating chamber (11) and plasma polymerization chamber (12) are both opened by disconnecting the second chamber part (11b) from the first chamber part (11a) of the coating chamber (11) and by disconnecting the second chamber part (12b) from the first chamber part (12a) of the plasma polymerization chamber (12). The component (1) can also be transferred from the coating chamber (11) to the plasma polymerization chamber (12) under atmosphere.

FIG. 1E only shows the plasma activation chamber (10), coating chamber (11) and plasma polymerization chamber (12), all in a closed state, and the plasma polymerization chamber (12) has a tool (17) for plasma polymerization, which is activated in order to apply a protective coating to the applied coat on the component (1).

The second chamber parts (10b, 11b and 12b) are closed separately from each other and shown in an open state. The vacuum coating system (100) has two chamber parts (10b, 11b and 12b) that are mechanically connected to each other so that, unlike the simple, schematic depiction, all the second chamber parts (10b, 11b and 12b) are opened or closed.

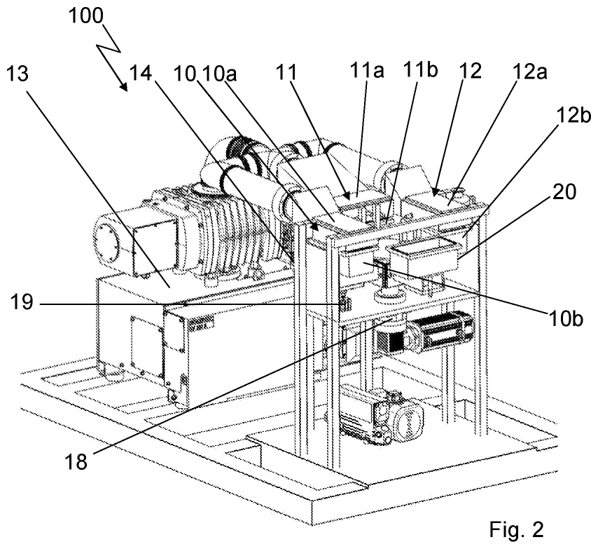

FIG. 2 shows a schematic perspective view of a vacuum coating system (100) for coating surfaces of a component under vacuum, and a plasma activation chamber (10) is provided for plasma activation of the component surface to be coated. Furthermore, a coating chamber (11) is provided for applying the coat and a plasma polymerization chamber (12) is provided for creating a protective coating on the applied coating using plasma polymerization, whereby only two of the three chambers can be present.

All three chambers (10, 11 and 12) are in an arrangement on a shared design, and all the chambers (10, 11 and 12) are divided into two chamber parts. The plasma activation chamber (10) features a first chamber part (10a) and a second chamber part (10b), the coating chamber (11) features a first chamber part (11a) and a second chamber part (11b) and the plasma polymerization chamber (12) features a first chamber part (12a) and a second chamber part (12b). The first chamber parts (10a, 11a and 12a) are arranged on the vacuum coating system design such that they cannot move and are connected with a vacuum pump (13). The second chamber parts arranged on the bottom (10b, 11b and 12b) are connected with a rotary indexing table (18) and can be moved up together with a lifting cylinder (19) to ensure that the second chamber parts (10b, 11b and 12b) can be sealed on the system against the first chamber parts (10a, 11a and 12a) and can be disconnected again from this system. If the lifting cylinder (19) moves up, then the second chamber parts (10b, 11b and 12b) form a seal on the system against the first chamber parts (10a, 11a and 12a). If the components are in the respective second chamber parts (10b, 11b and 12b), they can be moved with the second chamber parts (10b, 11b and 12b).

The design has three first chamber parts (10a, 11a and 12a) and four second chamber parts (10b, 11b, 12b and 20). The surplus second part (20) is used as an open chamber part (20) so that the surface-metallized component (1) can be removed from this open chamber part and an another component (1) can be inserted for coating. The second chamber parts (10b, 11b, 12b and 20) have an identical design, making it possible to switch the second chamber parts (10b, 11b, 12b and 20) with the first chamber parts (10a, 11a and 12a). The removal and insertion of components can be automated.

In addition to the vacuum pump (13), an auxiliary vacuum pump (14) is set up that is simply connected with the coating chamber (11a) and is designed to generate a stronger vacuum in the coating chamber (11a). Both the vacuum pump (13) and auxiliary vacuum pump (14) are connected to the first chamber parts (10a, 11 a and 12a), and the auxiliary vacuum pump (14) is simply connected to the first chamber part (11a) of the coating chamber (11).

The design of the invention is not limited to the preferred embodiment specified here. Rather, a number of variants are conceivable, which make use of the solution presented here, including in designs of a fundamentally different type. All of the features and/or advantages arising from the claims, description or drawings, including design details, physical layout and process steps, may be vital to the invention both by themselves and in a wide variety of combinations.

### REFERENCE NUMERAL LIST

100 Vacuum coating system
1 Component
10 Plasma activation chamber
10a First chamber part
10b Second chamber part
11 Coating chamber
11a First chamber part
11b Second chamber part
12 Plasma polymerization chamber
12a First chamber part
12b Second chamber part
13 Vacuum pump
14 Auxiliary vacuum pump
15 Plasma activation tool
16 Coat application tool
17 Plasma polymerization tool
18 Rotary indexing table
19 Lifting cylinder
20 Second chamber part

1. A procedure for coating surfaces of a component under vacuum using a vacuum coating system, the procedure comprising of the following process steps:
at least two of:
a) plasma activation of the component surface to be coated in an evacuated plasma activation chamber;
b) applying the coat in an evacuated coating chamber; and
c) plasma polymerization to create a protective coating on the applied coat in an evacuated plasma polymerization chamber,
wherein the respective plasma activation chamber and/or coating chamber and/or plasma polymerization chamber are ventilated and opened between at least two of the aforementioned process steps, and the component is fed to the subsequent process step.

2. The procedure in accordance with claim 1, wherein the plasma activation chamber is ventilated and opened after plasma activation and the component from the plasma activation chamber is transferred to the coating chamber and/or
the coating chamber is ventilated and opened after the coat is applied and the component from the coating chamber is transferred to the plasma polymerization chamber.

3. The procedure in accordance with claim 1, wherein several components are coated consecutively in a cycle sequence in the vacuum coating plant, whereby evacuation, ventilation and opening of the plasma activation chamber, coating chamber and plasma polymerization chamber are performed simultaneously.

4. The procedure in accordance with claim 1, wherein the vacuum is generated simultaneously in the plasma activation chamber, in the coating chamber and in the plasma polymerization chamber using a shared vacuum pump.

5. The procedure in accordance with claim 1, wherein, for more powerful evacuation of the coating chamber, there is an auxiliary vacuum pump that is activated in the coating chamber and plasma polymerization chamber by the vacuum pump for further evacuation of the coating chamber after mutual evacuation of the plasma activation chamber.

6. The procedure in accordance with claim 1, wherein the process steps for inserting components, evacuation, the respective process flow, ventilation and opening the plasma activation chamber, coating chamber and plasma polymerization chamber are carried out simultaneously.

7. A vacuum coating system for coating the surfaces of a component under vacuum, the system comprising:
at least one of a plasma activation chamber for plasma activation of the component surface to be coated, a coating chamber for applying the coat, and a plasma polymerization chamber for creating a protective coating on the applied coating using plasma polymerization,
whereby those of the plasma activation chamber, coating chamber and plasma polymerization chamber that are present each have a first chamber part, in which tools for plasma activation, applying the coat, and/or plasma polymerization as appropriate are designed, and
whereby those of the plasma activation chamber, coating chamber and/or plasma polymerization chamber as present each have a second chamber part that is designed to hold the component,
wherein the second chamber parts are arranged against the first chamber parts so they can move and, as a result, can be ventilated, switched in cycles, closed again and evacuated between at least two process steps when the components are switched.

8. The vacuum coating system in accordance with claim 7, wherein a vacuum pump generates the vacuum simultaneously in those of the plasma activation chamber, coating chamber and/or plasma polymerization chamber that are present using a shared vacuum pump.

9. The vacuum coating system in accordance with claim 8, wherein the vacuum pump is connected to the first chamber parts.

10. The vacuum coating system in accordance with claim 7 wherein the second chamber parts have a design compatible with their respective first chamber parts.

11. The vacuum coating system in accordance with claim 7, wherein the second chamber parts are held in a rotary indexing table and can be moved against the first chamber parts using the rotary indexing table.
